(19) United States
(12) Patent Application Publication
(10) Pub. No.: US 2016/0126440 A1
(43) Pub. Date: May 5, 2016

(54) METHOD OF PRODUCING NANOPARTICLES, METHOD OF PRODUCING THERMOELECTRIC MATERIAL, AND THERMOELECTRIC MATERIAL

(71) Applicant: Sumitomo Electric Industries, Ltd., Osaka-shi, Osaka (JP)

(72) Inventors: Masahiro ADACHI, Itami-shi (JP); Akira NAKAYAMA, Osaka-shi (JP); Yoshiyuki YAMAMOTO, Itami-shi (JP)

(21) Appl. No.: 14/895,266

(22) PCT Filed: May 30, 2014
(86) PCT No.: PCT/JP2014/064468

§ 371 Date: Dec. 2, 2015

(30) Foreign Application Priority Data
Jun. 4, 2013 (JP) 2013-117932
Oct. 31, 2013 (JP) 2013-226739
Feb. 27, 2014 (JP) PCT/JP2014/054868

(51) Int. Cl. H01L 35/26; H01L 35/34; H01L 35/22

(52) U.S. Cl. CPC H01L 35/26; H01L 35/22; H01L 35/34

(57) ABSTRACT

A method of producing nanoparticles in a base material made of a semiconductor material including a base material element, each nanoparticle including the base material element and a heterogeneous element different from the base material element includes: a layering step of alternately layering a first layer and a second layer, the first layer including the heterogeneous element, the second layer not including the heterogeneous element; and an annealing step of forming the nanoparticles in the base material by performing an annealing treatment onto a layered structure including the first layer and the second layer layered on each other. In the layering step, the base material element is included in at least one of the first layer and the second layer, and the second layer is formed to be thicker than the first layer.

### TECHNICAL FIELD

The present invention relates to a method of producing nanoparticles, a method of producing a thermoelectric material, and a thermoelectric material produced by the foregoing production method.

### BACKGROUND ART

A thermoelectric material converts a temperature difference (thermal energy) into electric energy, and has performance indicated by a figure of merit Z represented by the following formula (1):

Z=α²S/κ Formula (1)

where α represents Seebeck coefficient (V/K) of the thermoelectric material, S represents electric conductivity (S/m) of the thermoelectric material, and κ represents thermal conductivity (W/mK) of the thermoelectric material. Z has a dimension of reciprocal of the temperature, and ZT, which is obtained by multiplying figure of merit Z by absolute temperature T, has a dimensionless value. This ZT is referred to as “dimensionless figure of merit”, which is used as an index indicating performance of the thermoelectric material.

In order to broadly utilize such a thermoelectric material, it is required to further improve the performance thereof. From the formula (1), in order to improve efficiency of the thermoelectric material, it is understood to be effective to increase the Seebeck coefficient and the electric conductivity and decrease the thermal conductivity. For example, it is known (for example, L. D. Hicks et al., PRB 47 (1993) 12727 (Non-Patent Document 1); and L. D. Hicks et al., PRB 47 (1993) 16631 (Non-Patent Document 2)) or proved (for example, L. D. Hicks et al., PRB (1996) R10493 (Non-Patent Document 3); and Y. Okamoto et al., JJAP 38 (1999) L946 (Non-Patent Document 4)) that quantum well and quantum wire provide carriers in low dimensions and increase of phonon scattering, thereby controlling the Seebeck coefficient and the thermal conductivity.

Moreover, a thermoelectric material having carriers in lower dimensions by forming particles is known (Japanese Patent Laying-Open No. 2003-31860 (Patent Document 1); Japanese Patent Laying-Open No. 2002-76452 (Patent Document 2); and Japanese Patent Laying-Open No. 2011-3741 (Patent Document 3)); however, variation in particle size is large and the particle size is not controlled, thus making it difficult to sufficiently improve thermoelectric property.

In addition, as an example in which carriers are attained in low dimensions, it has been reported that a thin film of SiGeAu is annealed to form nanoparticles of SiGe in the thin film, thereby improving thermoelectric property as compared with a bulk SiGe (H. Takiguchi et al., JJAP 50 (2011) 041301 (Non-Patent Document 5)).

### CITATION LIST

### Patent Document

PTD 1: Japanese Patent Laying-Open No. 2003-31860

PTD 2: Japanese Patent Laying-Open No. 2002-76452

PTD 3: Japanese Patent Laying-Open No. 2011-3741

### Non Patent Document

NPD 1: L. D. Hicks et al., PRB 47 (1993) 12727

NPD 2: L. D. Hicks et al., PRB 47 (1993) 16631

NPD 3: L. D. Hicks et al., PRB (1996) R10493

NPD 4: Y. Okamoto et al., JJAP 38 (1999) L946

NPD 5: H. Takiguchi et al., JJAP 50 (2011) 041301

### SUMMARY OF INVENTION

### Technical Problem

According to the method described in Non-Patent Document 5, phonon scattering is improved by the formed nanoparticles and the thermal conductivity can be reduced; however, the Seebeck coefficient cannot be sufficiently improved. The present invention has an object to provide a method of producing nanoparticles included in a thermoelectric material having more excellent thermoelectric property, a method of producing the thermoelectric material, and the thermoelectric material.

### Solution to Problem

As a result of diligent study, the present inventor has found that too small a distance between the nanoparticles produced by the method described in Non-Patent Document 5 leads to a large overlap integral wave function of carriers (free electrons or free holes) and sufficient quantum effect, i.e., increase in density of states is accordingly not provided, thus failing to sufficiently improve the Seebeck coefficient. Then, the present inventor has arrived at the present invention by finding a method of controlling a distance between the nanoparticles to be appropriate to improve the Seebeck effect.

Specifically, the present invention is directed to a method of producing nanoparticles in a base material made of a semiconductor material including a base material element, each nanoparticle including the base material element and a heterogeneous element different from the base material element, the method including: a layering step of alternately layering a first layer and a second layer, the first layer including the heterogeneous element, the second layer not including the heterogeneous element; and an annealing step of forming the nanoparticles in the base material by performing an annealing treatment onto a layered structure including the first layer and the second layer layered on each other, in the layering step, the base material element being included in at least one of the first layer and the second layer, the second layer being formed to be thicker than the first layer.

In one embodiment of the present invention, the base material element is Si and Ge, the heterogeneous element is Au, Cu, B, or Al, and in the layering step, the first layer includes Ge as the base material element, and the second layer includes Si as the base material element.

In another embodiment of the present invention, the base material element is N and Ga, the heterogeneous element is In or Al, and in the layering step, the first layer and the second layer include N and Ga as the base material element.

In the layering step, the first layer preferably has a thickness of 2 to 8 nm, and an average particle size of the nanoparticles formed in the annealing step is preferably 1 to 25 nm, and an average distance between the nanoparticles is preferably 3 to 25 nm. The annealing step may be performed after the layering step or at the same time as the layering step.

Further, the present invention is directed to a method of producing a thermoelectric material including nanoparticles in a thin film made of a semiconductor material including a base material element, each nanoparticle including the base material element and a heterogeneous element different from the base material element, the method including: a layering step of alternately layering a first layer and a second layer, the first layer including the heterogeneous element, the second layer not including the heterogeneous element; and an annealing step of forming the nanoparticles in the thin film by performing an annealing treatment onto a layered structure including the first layer and the second layer layered on each other, in the layering step, the base material element being included in at least one of the first layer and the second layer, the second layer being formed to be thicker than the first layer.

Further, the present invention is directed to a thermoelectric material produced by the production method described above. In the thermoelectric material, an average particle size of the nanoparticles is preferably 1 to 25 nm, and an average distance between the nanoparticles is preferably 3 to 25 nm.

### Advantageous Effects of Invention

When a material including nanoparticles produced by the production method of the present invention is used as a thermoelectric material, a thermoelectric material exhibiting excellent thermoelectric property can be obtained.

### BRIEF DESCRIPTION OF DRAWINGS

FIG. 1 is a cross sectional view schematically showing a layered structure in a first embodiment when a layering step has been performed once and an annealing treatment has not been performed yet.

FIG. 2 is a cross sectional view schematically showing a layered structure in a second embodiment when the layering step has been performed once and the annealing treatment has not been performed yet.

FIG. 3(A) shows a bright-field STEM image of the layered structure after the layering step and before the annealing step in the sample of Example 1, and FIG. 3(B) shows an enlarged view of FIG. 3(A).

FIG. 4(A) shows a low-angle side diffraction pattern in the sample of Example 1 before the annealing step, and FIG. 4(B) shows a high-angle side diffraction pattern in the sample of Example 1 before the annealing step.

FIG. 5(A) shows a low-angle side diffraction pattern in the sample of Example 1 after the annealing step, and FIG. 5(B) shows a high-angle side diffraction pattern in the sample of Example 1 after the annealing step.

FIG. 6 shows a high-resolution TEM image of the sample of Example 1 after the annealing step.

FIG. 7(A) shows a diffraction image of the high-resolution TEM image of FIG. 6, and FIG. 7(B) shows a formed image in a specific direction as obtained by Fourier transformation of the diffraction image.

FIG. 8(A) shows a diffraction image of the high-resolution TEM image of FIG. 6 and FIG. 8(B) shows a formed image in a specific direction different from that of FIG. 7(B) as obtained by Fourier transformation of the diffraction image.

FIG. 9 shows a high-resolution TEM image of the sample of Comparative Example 1 after the annealing step.

FIG. 10(A) shows a diffraction image of the high-resolution TEM image of FIG. 9, and FIG. 10(B) shows a formed image in a specific direction as obtained by Fourier transformation of the diffraction image.

FIG. 11(A) shows a diffraction image of the high-resolution TEM image of FIG. 9, and FIG. 11(B) shows a formed image in a specific direction different from that of FIG. 10(B) as obtained by Fourier transformation of the diffraction image.

FIG. 12 shows a result of measurement of a Seebeck coefficient.

FIG. 13 shows a result of measurement of thermal conductivity.

FIG. 14 shows a result of measurement of electric conductivity.

FIG. 15 shows a result of finding dimensionless figure of merit ZT.

FIG. 16 is a diagram of plotting a relation between the film thickness of the second layer and average particle distance found by a measurement method 1.

FIG. 17 is a diagram of plotting a relation between the film thickness of the second layer and average particle distance found by a measurement method 2.

FIG. 18 is a diagram of plotting a relation between the film thickness of the second layer and average particle distance found by a measurement method 3.

FIG. 19 is a diagram of plotting a relation between the film thickness of the first layer and average particle distance found by a measurement method 4.

FIG. 20 is a cross sectional view schematically showing a layered structure in a third embodiment when a layering step has been performed once and an annealing treatment has not been performed yet.

FIG. 21 is a cross sectional view schematically showing a layered structure in a fourth embodiment when a layering step has been performed once and an annealing treatment has not been performed yet.

FIG. 22(A) shows a bright-field STEM image of a sample 7, FIG. 22(B) shows a bright-field STEM image of a sample 8, and FIG. 22(C) shows a bright-field STEM image of a sample 9.

FIG. 23 shows a result of measurement of thermoelectric voltage of sample 7.

FIG. 24 shows a result of measurement of thermoelectric voltage of sample 9.

FIG. 25(A) shows a model for sample 7 when a temperature difference is not more than 1K, and FIG. 25(B) shows a model for sample 7 when the temperature difference is more than 1K.

FIG. 26(A) shows a bright-field STEM image of the sample of Example 2 before the annealing step, and FIG. 26(B) shows a bright-field STEM image of the sample of Example 2 after the annealing step.

### DESCRIPTION OF EMBODIMENTS

[Method of Producing Nanoparticles]

The present invention is directed to a method of producing nanoparticles in a base material made of a semiconductor material including a base material element, each nanoparticle including the base material element and a heterogeneous element different from the base material element, the method including: a layering step of alternately layering a first layer and a second layer, the first layer including the heterogeneous element, the second layer not including the heterogeneous element; and an annealing step of forming the nanoparticles in the base material by performing an annealing treatment onto a layered structure including the first layer and the second layer layered on each other. In the layering step, all of the base material element is included in at least one of the first layer and the second layer, and the second layer is formed to be thicker than the first layer.

Thickness T₂ of the second layer is thicker than thickness T₁ of the first layer, and preferably satisfies the following relation: T₁<T₂≦3T₁. With such formation, it has been found that when the base material including the nanoparticles formed through the annealing treatment is used as a thermoelectric material, improved Seebeck coefficient and large dimensionless figure of merit ZT are attained as compared with, for example, a case where the first and second layers are layered on each other in the layering step to satisfy T₁=T₂. Specifically, it is possible to obtain a thermoelectric material having a Seebeck coefficient of not less than 3 mV/K. Moreover, it is possible to obtain a thermoelectric material having a dimensionless figure of merit ZT of not less than 10. This is considered due to the following reason. A distance between the nanoparticles in the first layers is controlled by the thickness of second layer and the weak binding of carriers (electrons or holes) resulting from the nanoparticles is controlled appropriately by the second layer, thereby improving the Seebeck coefficient.

Preferably in the production method of the present invention, when a desired particle distance between the nanoparticles to be formed is represented by G_{d}, a thickness T₂ of the second layer is determined in the layering step so as to satisfy the following formula (2). It should be noted that by employing thickness T₂ of the second layer determined in this way, nanoparticles can be formed to have an average particle distance Gₘ satisfying the following formula (3) after the annealing step. The step of deriving the formulas (2) and (3) will be described later.

G_{d}=(2.3±σ₁)T₂−(1.3±σ₂)(nm) Formula (2), and

Gₘ=(2.3±σ₁)T₂−(1.3±σ₂)(nm) Formula (3),

where each of σ₁ and σ₂ represents a standard deviation, σ₁ satisfies 0≦σ₁≦0.1, and σ₂ satisfies 0≦σ₂≦1.9.

Average distance Gₘ between the nanoparticles produced by the production method of the present invention is preferably 3 to 25 nm, and is more preferably 3 to 10 nm. With such a particle distance, high Seebeck coefficient and large dimensionless figure of merit ZT can be obtained. It should be noted that the distance between the nanoparticles in the present specification refers to the shortest distance between ends of the particles measured using an electron microscope (two-dimensional plane projection image), and the average distance refers to an arithmetic mean of distances between a sufficient number of particles. In the present application, the arithmetic mean of distances between 22 particles was found as the average distance. The distance between the nanoparticles can be adjusted by the thickness of the second layer.

Preferably in the production method of the present invention, when a desired particle size of the nanoparticles is represented as X_{d}, a thickness T₁ of the first layer is determined in the layering step to satisfy the following formula (4). It should be noted that by employing thickness T₁ of the first layer determined in this way, nanoparticles can be formed to have average particle size Xₘ satisfying the following formula (5) after the annealing step. The step of deriving the formulas (4) and (5) will be described later.

X_{d}=(32±σ₃)T₁−(81±σ₄)(nm) Formula (4), and

Xₘ=(32±σ₃)T₁−(81±σ₄)(nm) Formula (5),

where each of σ₃ and σ₄ represents a standard deviation, σ₃ satisfies 0≦σ₃≦7, and σ₄ satisfies 0≦σ₄≦20.

Average particle size Xₘ of the nanoparticles produced by the production method of the present invention is preferably 1 to 25 nm, and is more preferably 5 to 25 nm. With such a particle size, high Seebeck coefficient and large dimensionless figure of merit ZT can be obtained. It should be noted that in the present specification, the particle size refers to a longer diameter of a particle measured from an image (two-dimensional plane projection image) obtained using an electron microscope, and the average particle size refers to an arithmetic mean of the particle sizes of a sufficient number of particles. In the present application, the arithmetic mean of particle sizes of 22 particles was found as the average particle size. The particle sizes of the nanoparticles can be adjusted by the thickness of the first layer, the thickness of the second layer, the atomic concentration of the heterogeneous element in the first layer, a condition of the annealing treatment for the layered structure including the first layer and the second layer layered on each other, and the like.

In order to obtain such nanoparticles having the particle sizes and distance therebetween, the first layer preferably has a thickness of 2 to 8 nm, and the second layer preferably has a thickness of 2.5 to 12 nm.

Examples of the semiconductor material used for the base material in the production method include: silicon germanium; gallium nitride; aluminum nitride; boron nitride; a bismuth tellurium-based material such as Bi₂Te₃; Pb₂Te₃; a magnesium silicide-based material; and the like. When the base material is silicon germanium, the base material element is Si and Ge, and examples of the heterogeneous element include Au, Cu, B, Al, P, and the like. When the base material is gallium nitride, the base material element is N and Ga, and examples of the heterogeneous element include In, Al, B, and the like. When the base material is a bismuth tellurium-based material, the base material element is Bi and Te or Pb, and examples of the heterogeneous element include Au, Cu, B, Al, P, and the like. When the base material is a magnesium silicide-based material, the base material element is Mg and Si and examples of the heterogeneous element include Au, Cu, B, Al, P, and the like.

In the layering step, each layer can be provided using a raw material including an element constituting each layer, by means of a molecular beam epitaxy method (MBE), an electron beam method (EB), a sputtering method, a metal-organic vapor phase epitaxy method (MOVPE), an evaporation method, or the like. The atomic concentration of the heterogeneous element in the first layer is preferably 0.5 to 50 atomic %. The first layer may be constituted of a single layer or a plurality of layers. When the first layer is constituted of a plurality of layers, the first layer may be a layered structure including: a layer including the base material element; and a layer including the heterogeneous element. In the layering step, all of the base material element is included in at least one of the first layer and the second layer. For example, when the base material is silicon germanium, the first layer and the second layer can be formed such that Ge is included in the first layer as the base material element and Si is included in the second layer as the base material element. For example, when the base material is gallium nitride, the first layer and the second layer can be formed such that N and Ga are included in each of the first layer and the second layer. In the layering step, first and second layers can be alternately layered, for example, for 1 to 1000 times. The number of the layered first layers substantially corresponds to the number of the nanoparticles to be formed in the thickness direction.

In the embodiment of the present invention, the layering step is a step of alternately layering the first layer and the second layer on a substrate structure. The substrate structure preferably has an uppermost layer that is in contact with at least the first layer and that is formed of a material capable of having solubility of the heterogeneous element. With such a configuration, when the heterogeneous element is diffused by the annealing treatment, the heterogeneous element can be diffused also in the substrate structure, thereby preventing the heterogeneous element from being precipitated intensively at a specific portion, in particular, a portion of the first layer in contact with the substrate structure. If the heterogeneous element is precipitated intensively at the specific portion, such a specific portion may constitute a leak path, thereby presumably causing decreased thermoelectric property when the layered structure including the nanoparticles produced by the method of the embodiment of the present invention is used as a thermoelectric material. It should be noted that the decreased thermoelectric property resulting from the leak path is likely to be noticeable when the temperature difference caused in the thermoelectric material is large, for example, when the temperature difference is more than than a temperature difference of 1 K. Accordingly, a sufficient thermoelectric property can be obtained also by a substrate structure having no uppermost layer described above, and particularly when the temperature difference caused in the thermoelectric material is small such as not more than 1 K, a sufficient thermoelectric property can be obtained also by the substrate structure having no uppermost layer.

The above-described material of the uppermost layer is not limited as long as it is capable of having solubility of the heterogeneous element included in the first layer under the treatment condition in the annealing step, and examples of such a material include Si, a semiconductor, glass, ceramics, an organic substance such as PEDOT (poly(3,4-ethylenedioxythiophene)), and the like. Examples of the glass include amorphous glass, porous glass, and the like. As the material of the uppermost layer, a material having a slow rate of diffusing the heterogeneous element is more preferable. This is due to the following reason: with a slower rate of diffusing the heterogeneous element, it is easier to control the diffusion of the heterogeneous element in the uppermost layer. For example, when the heterogeneous element is Au, Si and Ge are exemplified as the material capable of having solubility of Au; however, Si is slower in rate of diffusing Au, so that it is more preferable to form the uppermost layer using Si. It is expected that the rate of diffusing the heterogeneous element in a material is correlated with affinity between the material and the heterogeneous element and the melting point of the material including the heterogeneous element.

The substrate structure may be a layered structure including the above-mentioned uppermost layer and another layer, or may be a single-layer structure only constituted of the uppermost layer. In the case of a layered structure, a layered structure in which an uppermost layer is formed on a substrate can be used, for example. The thickness of the uppermost layer is not particularly limited as long as the heterogeneous element can be prevented from being intensively precipitated at a particular portion of the first layer; however, the thickness is preferably not less than 5 nm, and more preferably not less than 15 nm. This is because the thickness of not less than 5 nm allows for sufficient inclusion of the heterogeneous element diffused under the treatment condition in the annealing step. It should be noted that the upper limit value is not particularly limited, but can be not more than 30 nm in view of cost, for example.

In the annealing step, the layered structure including the first and second layers layered on each other is subjected to the annealing treatment, thereby forming the nanoparticles in the base material. The annealing treatment herein refers to a treatment in which heating is performed until the atoms of the first layer are diffused and then cooling is performed. Therefore, the temperature and time of the annealing treatment differ depending on the material of the first layer. Moreover, by controlling the temperature, time, and heating rate in the annealing treatment, it is possible to adjust whether to form the nanoparticles and adjust the particle sizes of the formed nanoparticles.

The layering step and the annealing step may be performed independently or may be performed simultaneously. When they are performed independently, the annealing step is performed after completion of the layering step of alternately layering the first and second layers. When they are performed simultaneously, the layering step is performed under the conditions of the annealing treatment so as to perform the annealing treatment in the layering step simultaneously. When the steps are performed independently, the temperature is readily controlled, whereas when the steps are performed simultaneously, the number of steps can be reduced.

### First Embodiment

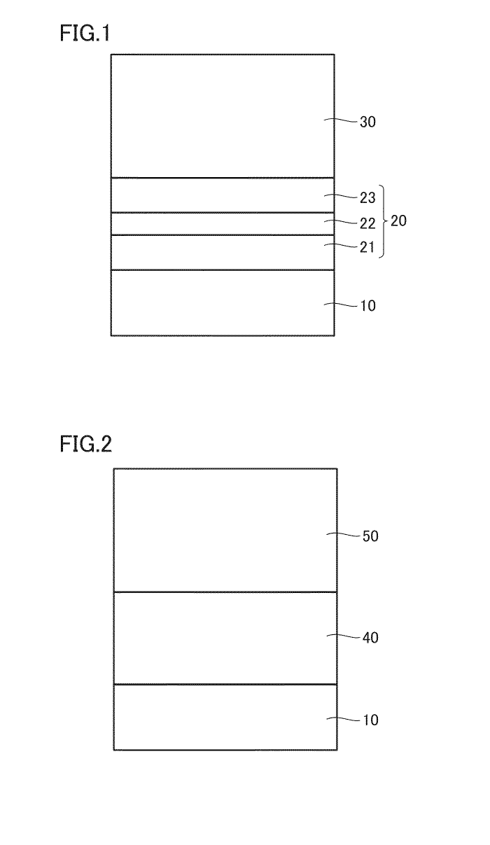

A first embodiment provides an example of a production method of the present invention in the case where a base material is silicon germanium and a heterogeneous element is Au. FIG. 1 is a cross sectional view schematically showing a layered structure when a layering step has been performed once and an annealing treatment has not been performed yet.

In the layering step of the present embodiment, first, a sapphire substrate 10 is prepared, Ge, Au, Ge are then deposited in this order by an MBE or EB method to form a first layer 20 constituted of an amorphous Ge (a-Ge) layer 21, a Au layer 22, and an amorphous Ge (a-Ge) layer 23, and then Si is deposited to form a second layer 30 constituted of an amorphous Si (a-Si) layer. In the MBE method, each of the materials, i.e., Ge, Au, and Si is heated by an electron beam method in a cell, thereby generating a molecular beam. Such layering of first layer 20 and second layer 30 is performed repeatedly for 60 times, thereby forming a layered structure. In the present embodiment, a-Ge layer 21 and Au layer 22 are formed as different layers in first layer 20 due to readiness in deposition; however, the deposition method is not limited to this as long as Ge and Au are included in first layer 20.

Then, the layered structure is subjected to an annealing treatment to form nanoparticles. With the annealing treatment, SiGe nanoparticles including Au are formed in the base material constituted of Si and Ge. In the present embodiment, it is considered that the nanoparticles are thus formed in the following mechanism: AuGe having an eutectic point lower than AuSi is first activated in first layer 20, and then Si of second layer 30 is moved thereinto, thereby forming SiGe nanoparticles including Au. It should be noted that the base material constituted of Si and Ge around the SiGe nanoparticles is amorphous SiGe, amorphous Ge, or amorphous Si.

In the present embodiment, in order to obtain a nanoparticle having a particle size of 1 to 25 nm, it is preferable that first layer 20 is set to have a thickness of not less than 2.0 nm and less than 5.0 nm, second layer 30 is set to have a thickness of not less than 3.0 nm and not more than 6.0 nm, and Au layer 22 in first layer 20 is set to have a thickness of not less than 0.1 nm and not more than 0.4 nm, for example. Moreover, the atomic concentration of Au in first layer 20 is set at 0.5 to 50 atomic %.

The annealing treatment is performed in the annealing step at a temperature that can be appropriately selected from a range of 200 to 800° C.; however, the annealing treatment is preferably performed at a temperature of 300 to 700° C. in order to obtain nanoparticles each having a particle size of 5 to 25 nm. The particle sizes of the nanoparticles are dependent on the thickness of each of first layer 20 and second layer 30 and the atomic concentration of the heterogeneous element; however, nanoparticles each having a particle size of 0.1 to 2 nm are likely to be obtained when the annealing treatment is performed at a temperature of 250° C., whereas nanoparticles each having a particle size of 20 to 100 nm are likely to be obtained when the annealing treatment is performed at a temperature of 750° C. The annealing treatment in the annealing step performed after the end of the layering step can be performed for 1 to 120 minutes, for example.

In the manner described above, the thin film including the SiGe nanoparticles including Au is formed in the base material constituted of Si and Ge. When this thin film is used as a thermoelectric material, the nanoparticles thus included provide decreased thermal conductivity and increased Seebeck coefficient as compared with those in the case where no such nanoparticles are included therein, whereby the thin film serves as a thermoelectric material having a high figure of merit. The increase in Seebeck coefficient is attained due to the following reasons: grain boundary diffusion are caused due to presence of the nanoparticles; and carriers can be more effectively confined in the nanoparticles. Furthermore, according to the production method of the present invention, the distance between the nanoparticles can be optimized to more effectively cause grain boundary diffusion, thereby further increasing the Seebeck coefficient.

### Second Embodiment

A second embodiment provides an example of a production method of the present invention in the case where the base material is gallium nitride and the heterogeneous element is In. FIG. 2 is a cross sectional view schematically showing a layered structure when a layering step has been performed once and an annealing treatment has not been performed yet.

In the layering step of the present embodiment, sapphire substrate 10 is first prepared, then, Ga, N, and In are deposited in this order by the MBE or EB method to form a first layer 40 constituted of an amorphous InGaN (a-InGaN) layer, and then Ga and N are deposited to form a second layer 50 constituted of an amorphous GaN (a-GaN) layer. In the MBE method, each of the materials, i.e., Ga and In is heated by a resistance heating method in a cell, thereby generating a molecular beam. N is supplied as nitrogen radical by way of radical discharge for N₂ gas. Such layering of first layer 40 and second layer 50 is performed repeatedly for 60 times, thereby forming a layered structure.

Then, the layered structure is subjected to an annealing treatment to form nanoparticles. With the annealing treatment, GaN nanoparticles including In are formed in the base material constituted of Ga and N. The base material constituted of Ga and N around the GaN nanoparticles is amorphous GaN.

In the present embodiment, in order to obtain nanoparticles each having a particle size of 1 to 10 nm, it is preferable that first layer 40 is set to have a thickness of not less than 2.5 nm and less than 3.0 nm and second layer 50 is set to have a thickness of not less than 4.0 nm and not more than 6.0 nm, for example. Moreover, the atomic concentration of In in first layer 40 is preferably set at 0.1 to 80 atomic %.

The annealing treatment is performed in the annealing step at a temperature that can be appropriately selected from a range of 150 to 1100° C.; however, the annealing treatment is preferably performed at a temperature of 300 to 800° C. in order to obtain nanoparticles each having a particle size of 1 to 10 nm. The annealing treatment in the annealing step performed after the end of the layering step can be performed for 1 to 120 minutes, for example.

In the manner described above, the thin film including the GaN nanoparticles including In is formed in the base material constituted of Ga and N. When this thin film is used as a thermoelectric material, the nanoparticles thus included provide decreased thermal conductivity and increased Seebeck coefficient as compared with those in the case where no such nanoparticles are included therein, whereby the thin film serves as a thermoelectric material having a high figure of merit. The increase in Seebeck coefficient is attained due to the following reasons: grain boundary diffusion is caused due to presence of the nanoparticles; and carriers can be effectively confined in the nanoparticles. Furthermore, according to the production method of the present invention, the distance between the nanoparticles can be optimized to more effectively cause grain boundary diffusion, thereby further increasing the Seebeck coefficient.

### Third Embodiment

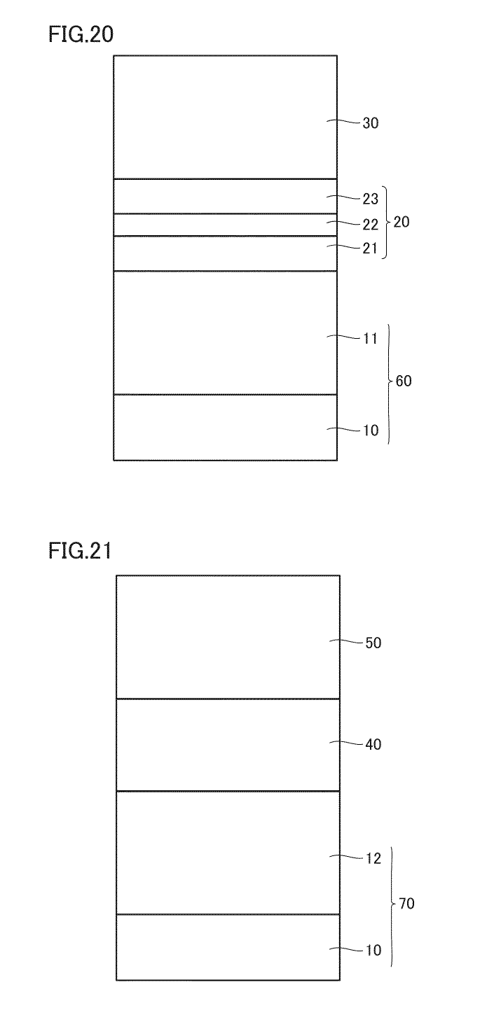

A third embodiment is different from the first embodiment only in that a substrate structure 60 is used instead of sapphire substrate 10. FIG. 20 is a cross sectional view schematically showing a layered structure when a layering step has been performed once and an annealing treatment has not been performed yet. Substrate structure 60 is constituted of sapphire substrate 10 and an uppermost layer 11, which is an amorphous Si (a-Si) layer. For substrate structure 60, sapphire substrate 10 is first prepared and then uppermost layer 11 is formed by depositing Si thereon by the MBE or EB method. The other steps are the same as those of the first embodiment and are therefore not described again. The layered structure including the nanoparticles produced in accordance with the present embodiment is configured such that Au is diffused in uppermost layer 11.

### Fourth Embodiment

A fourth embodiment is different from the second embodiment only in that a substrate structure 70 is used instead of sapphire substrate 10. FIG. 21 is a cross sectional view schematically showing a layered structure when a layering step has been performed once and an annealing treatment has not been performed yet. Substrate structure 70 is constituted of sapphire substrate 10 and an uppermost layer 12, which is an amorphous GaN (a-GaN) layer. For substrate structure 70, sapphire substrate 10 is first prepared and then uppermost layer 12 is formed by depositing Ga and N thereon by the MBE method. The other steps are the same as those of the second embodiment and are therefore not described again. The layered structure including the nanoparticles produced in accordance with the present embodiment is configured such that In is diffused in uppermost layer 12.

[Method of Producing Thermoelectric Material]

A method of producing a thermoelectric material in the present invention is such that the thin film including the nanoparticles formed by annealing the layered structure in the above-described method of producing the nanoparticles is employed as a thermoelectric material without any modification. Specifically, the method of producing a thermoelectric material in the present invention is a method of producing a thermoelectric material including nanoparticles in a thin film made of a semiconductor material including a base material element, each nanoparticle including the base material element and a heterogeneous element different from the base material element. The method includes: a layering step of alternately layering a first layer and a second layer, the first layer including the heterogeneous element, the second layer not including the heterogeneous element; and an annealing step of forming the nanoparticles in the thin film by performing an annealing treatment onto a layered structure including the first layer and the second layer layered on each other. In the layering step, all of the base material element is included in at least one of the first layer and the second layer, and the second layer is formed to be thicker than the first layer. The details of the layering step and the annealing step are as described above with regard to the method of producing the nanoparticles. Thus, by producing the thermoelectric material in this way, high Seebeck coefficient and large dimensionless figure of merit ZT can be obtained.

[Thermoelectric Material]

A thermoelectric material of the present invention is the thermoelectric material produced by the method of producing the thermoelectric material. That is, the thermoelectric material of the present invention includes the nanoparticles, the average particle size of the nanoparticles is preferably 1 to 25 nm and more preferably 5 to 25 nm, and the distance between the nanoparticles is preferably 3 to 25 nm and more preferably 3 to 10 nm. The thermoelectric material having the nanoparticles involving such particle distance and particle size can attain high Seebeck coefficient and large dimensionless figure of merit ZT. The Seebeck coefficient is preferably not less than 1 mV/K, more preferably, not less than 2 mV/K, and further preferably, not less than 3 mV/K, whereas dimensionless figure of merit ZT is preferably not less than 10.

Moreover, the thermoelectric material produced by the production method in the third or fourth embodiment is configured such that the heterogeneous element is diffused in the uppermost layer of the substrate structure. In such a configuration, the heterogeneous element is not precipitated intensively at a specific portion and a leak path can be prevented from being formed, whereby a high Seebeck coefficient can be obtained even when the temperature difference to be caused in the thermoelectric material is made large.

### EXAMPLES

[Experiment to Determine Formulas (2) to (5)]

Nanoparticles were formed using the production method of the first embodiment. Specifically, in the layering step, the first layer constituted of the a-Ge layer, the Au layer, and the a-Ge layer was deposited on the sapphire substrate such that the a-Ge layer, the Au layer, and the a-Ge layer respectively had thicknesses of 1.3 to 1.9 nm, 0.2 nm, and 1.3 to 1.9 nm, and then Si was deposited thereon to deposit the second layer constituted of the a-Si layer and having a thickness falling within a range of 2.6 to 5.2 nm. The concentration of Au in the first layer was set at 2.5 to 17 atomic %. Then, the step of layering the first and second layers was repeatedly performed for 60 times. Then, the layered structure was left in an RTA furnace of nitrogen atmosphere under an environment of 600° C. for 15 minutes to perform the annealing step by providing annealing treatment, thereby forming nanoparticles. From the samples thus produced, a relation between the thickness of the second layer and average distance Gₘ of the nanoparticles was found as in, for example, measurement methods 1 to 3 illustrated below, thereby deriving relational expressions of formulas (2) and (3). Moreover, from the samples thus produced, a relation between the thickness of the first layer and average particle size Xₘ of the nanoparticles was found as in, for example, a measurement method 4 illustrated below, thereby deriving relational expressions of formulas (4) and (5).

In each of measurement methods 1 to 4, six samples were produced in accordance with the above-described method. It should be noted that in three of the produced samples, the first and second layers were deposited using a molecular beam epitaxy method (MBE method), whereas in the other three of the produced samples, the first and second layers were deposited using an electron beam method (EB method).

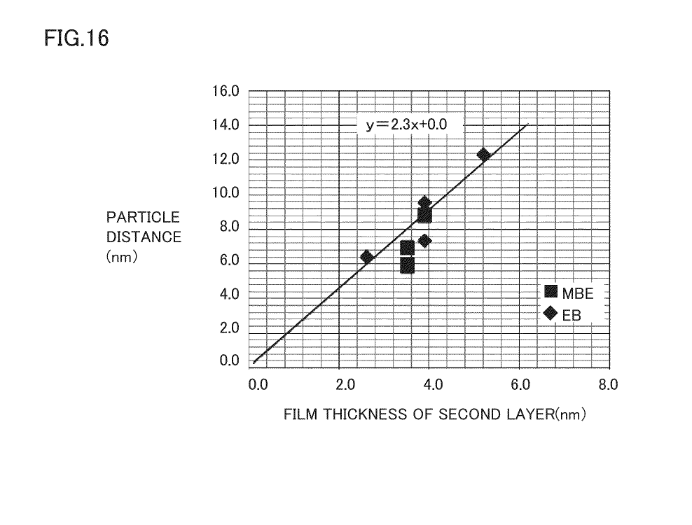

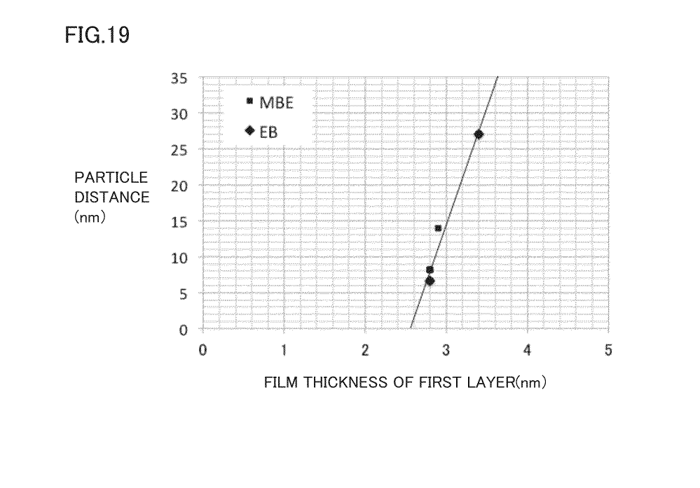

With measurement methods 1 to 3, an average particle distance Gₘ of the nanoparticles in each of the produced samples was found in a manner described below, and a relation between the film thickness of the second layer and average particle distance Gₘ was plotted in each of FIG. 16 to FIG. 18. Likewise, with measurement method 4, an average particle size Xₘ of the nanoparticles in the produced sample was found in a manner described below, and a relation between the film thickness of the first layer and average particle size Xₘ was plotted in FIG. 19.

(Measurement Method 1)

In measurement method 1, average particle distance G was found by actually measuring it from a high-resolution TEM (Transmission Electron Microscopy) image obtained using an electron microscope (device name: JEM-2100F provided by JEOL Co., Ltd.) after slicing into about 100 nm by FIB (Focused Ion Beam) in the layering direction, and from an FFT image obtained by performing FFT (Fast Fourier Transform) transformation to emphasize the periodic structure of the nano crystal. FIG. 16 is a diagram of plotting a relation between the film thickness of the second layer and average distance G found by measurement method 1. From the result shown in FIG. 16 with the least squares method, the following formula (3a) was derived:

G=2.3T₂.

(Measurement Method 2)

In measurement method 2, average distance G was found based on the following formula (6) derived by assuming that the nanoparticles were distributed uniformly and using crystallization rate η measured based on Raman scattering measurement and average radius r of the nanoparticles found by actual measurement from a high-resolution TEM (Transmission Electron Microscopy) image:

G=2(r/η^{(1/3)}−r).

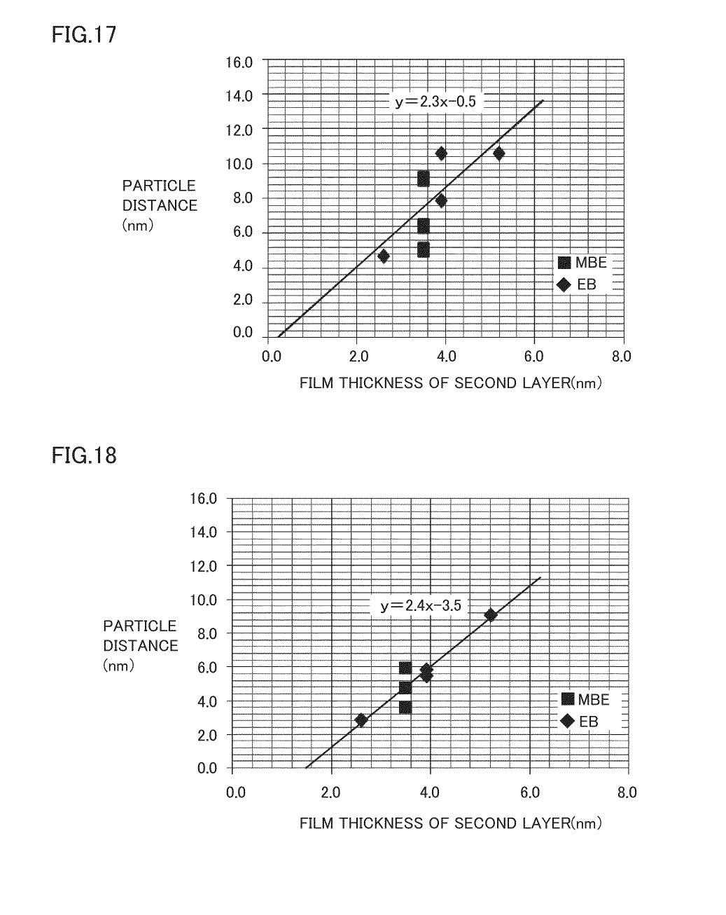

FIG. 17 is a diagram of plotting a relation between the film thickness of the second layer and distance G found by measurement method 2. From the result shown in FIG. 17, with the least squares method, the following formula (3b) was derived:

G=2.3T₂−0.5.

(Measurement Method 3)

In measurement method 3, crystallization rate η was measured from Raman scattering measurement and radius r of the nanoparticles was found from the Scherrer equation based on a result of measurement of X-ray diffraction (XRD). Then, using crystallization rater η and radius r, particle distance G was found from the formula (6). FIG. 18 is a diagram of plotting a relation between the film thickness of the second layer and particle distance G found by measurement method 3. From the result shown in FIG. 18, the following formula (3c) was derived:

G=2.4T₂−3.5.

(Measurement Method 4)

In measurement method 4, particle size X of the nanoparticles was found from the Scherrer equation based on a result of measurement of X-ray diffraction (XRD). Table 1 shows data in which the designed film thickness of the first layer and particle size X found using measurement method 4 in each of the six samples (samples 1 to 6), and FIG. 19 is a diagram of plotting the result of Table 1.

TABLE 1

| | Deposition | Designed Film Thickness of | Particle Size X |
|---|---|---|---|
| | Method | First Layer (nm) | (nm) |
| Sample 1 | MBE | 2.8 | 8.2 |
| Sample 2 | MBE | 2.8 | 6.6 |
| Sample 3 | MBE | 2.8 | 8.2 |
| Sample 4 | MBE | 2.9 | 14 |
| Sample 5 | EB | 2.8 | 6.6 |
| Sample 6 | EB | 3.4 | 27 |

From Table 1 and the result shown in FIG. 19, with the least squares method, the following formula (41) was derived:

X=32T₁−81.

### Example 1

Nanoparticles were formed using the production method of the first embodiment. Specifically, in the layering step, the first layer constituted of the a-Ge layer, the Au layer and the a-Ge layer was deposited on the sapphire substrate such that the a-Ge layer, the Au layer and the a-Ge layer respectively had thicknesses of 1.3 nm, 0.2 nm, and 1.3 nm and the first layer had a total thickness of 2.8 nm, and then Si was deposited to deposit the second layer constituted of the a-Si layer and having a thicknesses of 5.2 nm. Then, such a step was repeatedly performed for 60 times. It should be noted that the atomic concentration of Au in the first layer was set at 2.5 atomic %. Then, the layered structure was left in an RTA furnace (Rapid Thermal Anneal furnace) of nitrogen atmosphere under an environment of 600° C. for 15 minutes to perform the annealing step by providing an annealing treatment. It should be noted that because a desired particle size X_{d} of the nanoparticles was set at 10 nm and a desired particle distance G_{d} of the nanoparticles was set at 12 nm, thickness T₁ of the first layer in the present exam*, i.e., 2.8 mm, was determined to satisfy the formula (4), whereas thickness T₂ of the second layer, i.e., 5.2 nm, was determined to satisfy the formula (2).

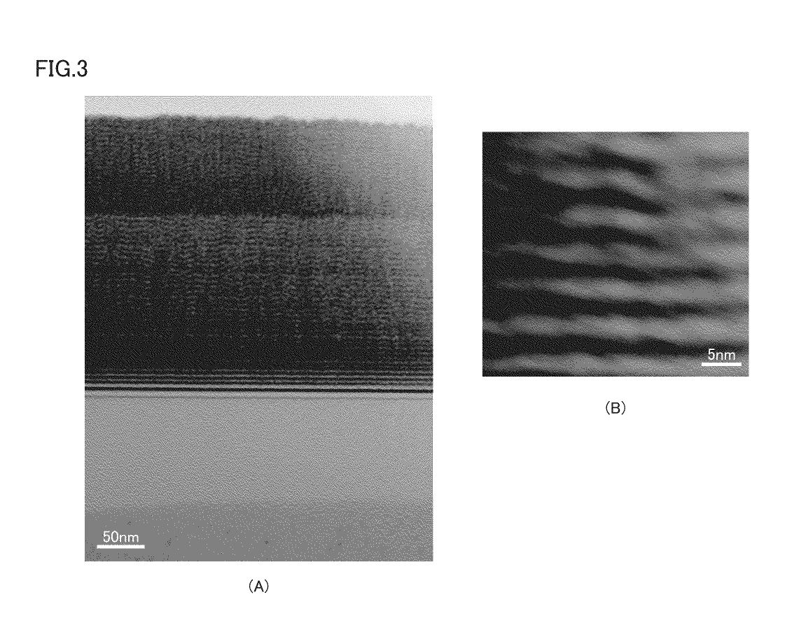

FIG. 3(A) shows a bright-field STEM (Scanning Transmission Electron Microscopy) image of the layered structure as obtained using an electron microscope (device name: JEM-2100F provided by JEOL Co., Ltd.) after the layering step and before the annealing step. FIG. 3(B) shows an enlarged image of the layering portion of the first and second layers of FIG. 3(A). From FIGS. 3(A) and (B), it was confirmed that the first and second layers were layered alternately. It should be noted that with EDX (energy dispersive X-ray spectroscopy) of the bright-field STEM image of FIG. 3(A), it was found that the a-Ge layer, the Au layer and the a-Ge layer in the first layer were substantially assimilated with one another and it was inferred that they were formed into a mixed crystal in the layering step.

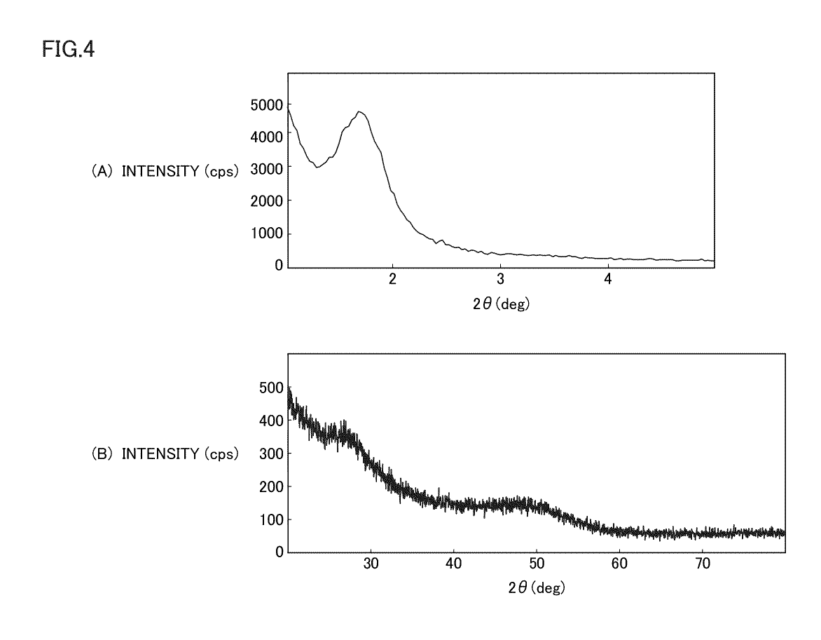

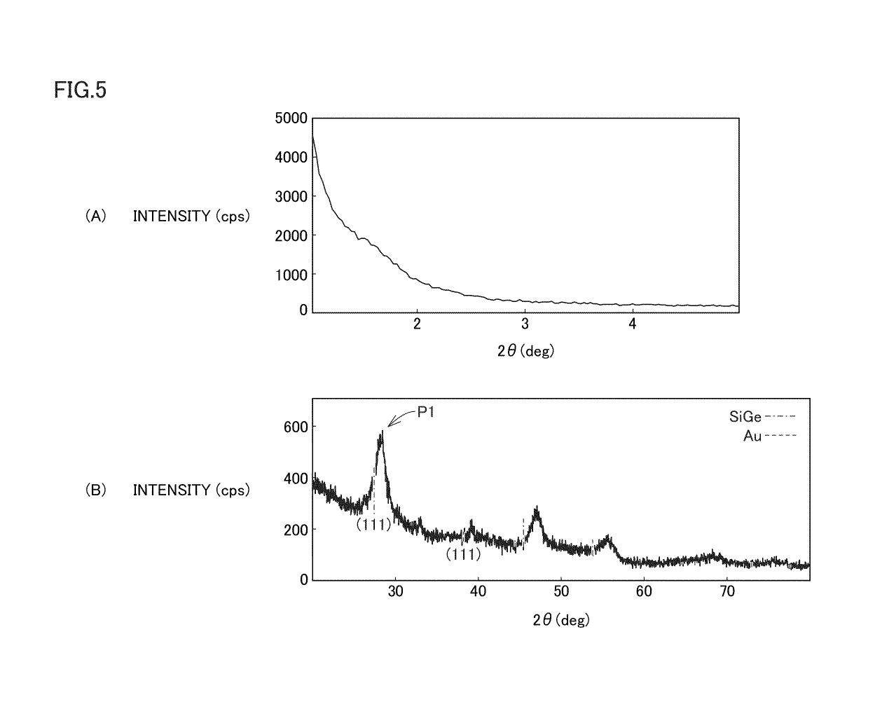

FIG. 4 show an X-ray diffraction pattern obtained by X-ray diffraction measurement performed onto the layered structure using an X-ray diffractometer after the layering step and before the annealing step. FIG. 4(A) shows a low-angle side diffraction pattern and FIG. 4(B) shows a high-angle side diffraction pattern. Moreover, FIG. 5 show an X-ray diffraction pattern of the layered structure after the annealing step. FIG. 5(A) shows a low-angle side diffraction pattern, and FIG. 5(B) shows a high-angle side diffraction pattern. In the low-angle side diffraction pattern, a peak was observed before the annealing step (FIG. 4(A)) whereas the peak was disappeared after the annealing step (FIG. 5(A)). This was presumably due to the following reason: the peak at the low-angle side corresponded to the periodic structure obtained by repeatedly layering the first and second layers and this periodic structure was disappeared by the annealing step. In the high-angle side diffraction pattern, no peak was observed before the annealing step (FIG. 4(B)) whereas an apparent peak was appeared after the annealing step (FIG. 5(B)). This is presumably due to the following reason: peak P1 observed in FIG. 5(B) corresponded to a crystal plane (111) of the SiGe crystal and therefore the SiGe crystal was formed by the annealing treatment.

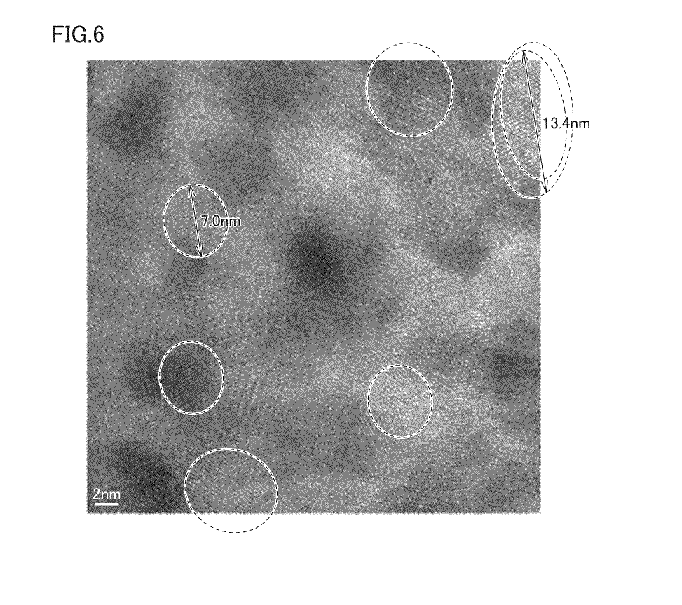

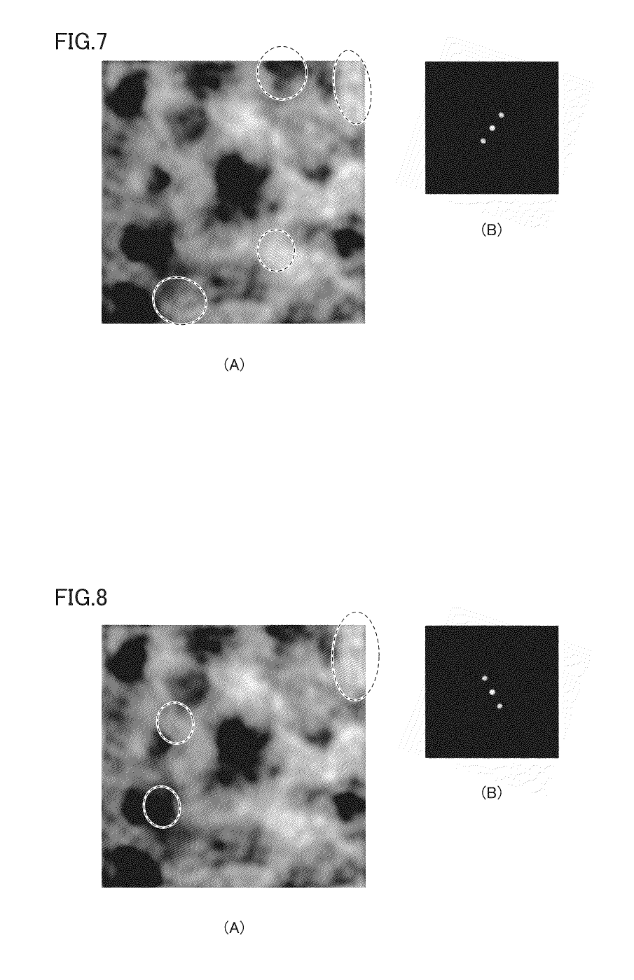

FIG. 6 shows a high-resolution TEM (Transmission Electron Microscopy) image obtained, using an electron microscope (device name: JEM-2100F provided by JEOL Co., Ltd.), after slicing the layered structure having been through the annealing step into about 100 nm by way of FIB (Focused Ion Beam) in the layering direction. In FIG. 6, regions surrounded by dotted lines are regions considered to be crystallized. Each of FIG. 7(A) and FIG. 8(A) shows a diffraction image of the high-resolution TEM image of FIG. 6, and each of FIG. 7(B) and FIG. 8(B) shows a formed image in a different specific direction as obtained by way of Fourier transformation of the diffraction image of each of FIG. 7(A) and FIG. 8(A). In the case of amorphous state in the high-resolution TEM image, no diffraction was observed, whereas in the case of crystallized state, diffraction resulting from crystal particles was observed. In FIG. 7(A) and FIG. 8(A), diffraction resulting from the crystal particles was observed in the regions surrounded by, for example, the dotted lines, so that it was found that the crystal structure was formed.

With the actual measurement of the particle sizes of the crystal particles in the high-resolution TEM image shown in FIG. 6, the particle sizes of the crystal particles were 5 to 14 nm and the average particle size thereof was 8 nm. Regarding the X-ray diffraction pattern shown in FIG. 5(B), when the half width of peak P1 corresponding to the crystal plane of SiGe was applied to the Scherrer equation to estimate the particle size of the crystal particle, the particle size of the crystal particle was 8.2 nm, which substantially corresponded to the value actually measured in the high-resolution TEM image shown in FIG. 6. In the high-resolution TEM image shown in FIG. 6, when a distance between crystal particles was actually measured, the distance was 5 to 25 nm and the average distance thereof was 14 nm. Therefore, particle size Xₘ of the obtained nanoparticle, i.e., 8.2 nm, satisfied the formula (5) in relation with thickness T₁ of the first layer, i.e., 2.8 mm. Moreover, average particle distance Gₘ of the obtained nanoparticles, i.e., 14 nm, satisfied the formula (3) in relation with thickness T₂ of the second layer, i.e., 5.2 nm.

### Comparative Example 1

Nanoparticles were produced using the same production method as that in Example 1 except that the thickness of the second layer in the layering step was 2.6 nm, which was thinner than the total thickness of the first layer, i.e., 2.8 nm.

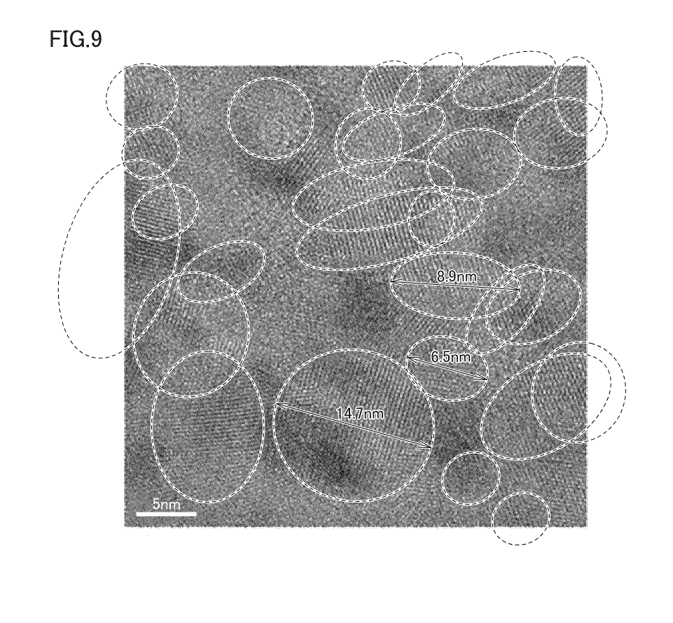

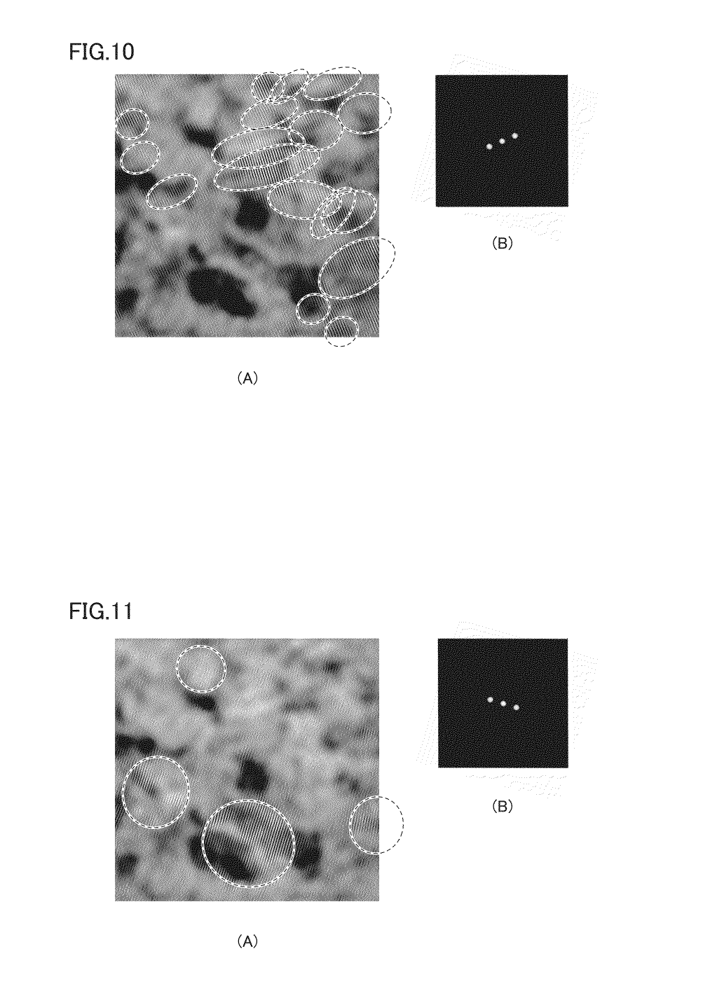

FIG. 9 shows a high-resolution TEM (Transmission Electron Microscopy) image obtained, using an electron microscope (device name: JEM-2100F provided by JEOL Co., Ltd.), after slicing the layered structure having been through the annealing step into about 100 nm by way of FIB (Focused Ion Beam) in the layering direction. In FIG. 9, regions surrounded by dotted lines are regions considered to be crystallized. Each of FIG. 10(A) and FIG. 11(A) shows a diffraction image of the high-resolution TEM image of FIG. 9, and each of FIG. 10(B) and FIG. 11(B) shows a formed image in a different specific direction as obtained by way of Fourier transformation of the diffraction image of each of FIG. 10(A) and FIG. 11(A). In the case of amorphous state in the high-resolution TEM image, no diffraction was observed, whereas in the case of crystallized state, diffraction resulting from crystal particles was observed. In FIG. 10(A) and FIG. 11(A), diffraction resulting from the crystal particles was observed in the regions surrounded by the dotted lines, so that it was found that the crystal structure was formed.

With the actual measurement of the particle sizes of the crystal particles in the high-resolution TEM image shown in FIG. 9, the particle sizes of the crystal particles were 4 to 15 nm and the average particle size thereof was 7 nm. In the high-resolution TEM image shown in FIG. 9, when a distance between crystal particles was actually measured, the distance was 0 to 3 nm and the average distance thereof was 1 nm.

[Evaluation]

The Seebeck coefficient, thermal conductivity, and electric conductivity of each of the samples of Example 1 and Comparative Example 1 were measured in a manner described below so as to evaluate thermoelectric property when used as a thermoelectric material.

(Measurement of Seebeck Coefficient)

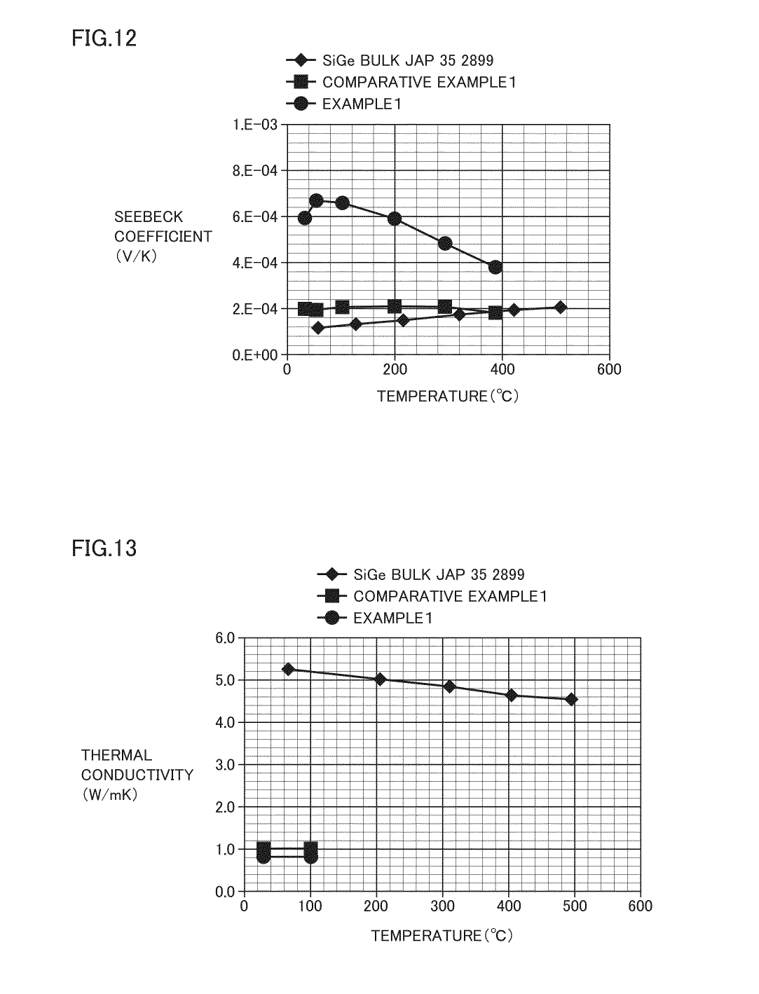

The Seebeck coefficient of each of the samples of Example 1 and Comparative Example 1 was measured using a thermoelectric property evaluation device (device name: ZEM3 provided by ULVAC-RIKO). FIG. 12 shows a result of measurement of the Seebeck coefficient of each of the samples of Example 1 and Comparative Example 1 and the Seebeck coefficient of bulk SiGe shown in Dismukes, J. P., et al., (1964) J. App. Phys. 35, 2899-2907 (JAP352899). The sample of Example 1 exhibited a high value near 0.7 mV/K, which was higher in value than that of the bulk SiGe. This is considered as an effect provided by the nanoparticles included. Moreover, the higher value than that of the sample of Comparative Example 1 is considered as an effect of the distance between the nanoparticles being optimized with respect to the particle sizes of the nanoparticles.

(Measurement of Thermal Conductivity)

The thermal conductivity of each of the samples of Example 1 and Comparative Example 1 was measured using a thermal conductivity measurement device (device name: TM3 provided by Bethel; measured by a 2ω method). FIG. 13 shows a result of measurement of the thermal conductivity of each of the samples of Example 1 and Comparative Example 1 and the thermal conductivity of the bulk SiGe shown in JAP352899. The sample of Example 1 exhibited a low thermal conductivity, which was not more than ⅕ of the bulk SiGe. This is considered as an effect of improved phonon scattering provided by the nanoparticles included.

(Measurement of Electric Conductivity)

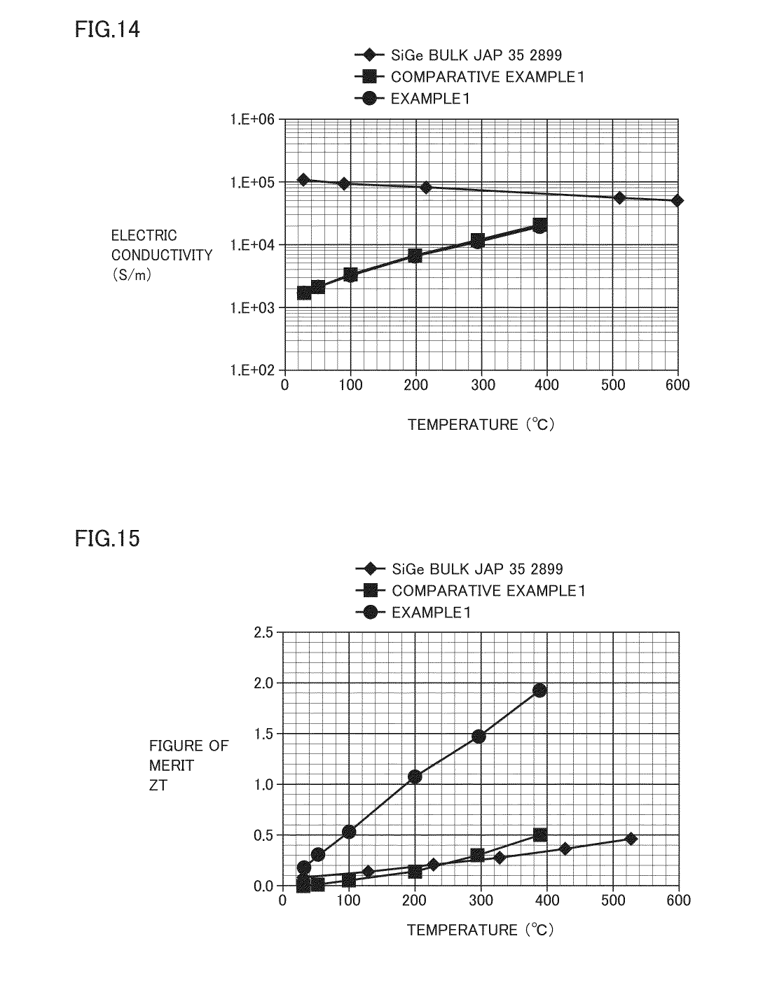

The electric conductivity of each of the samples of Example 1 and Comparative Example 1 was measured using an electric conductivity measurement device (device name: ZEM3 provided by ULVAC-RIKO). FIG. 14 shows a result of measurement of the electric conductivity of each of the samples of Example 1 and Comparative Example 1 and the electric conductivity of the bulk SiGe shown in JAP352899.

(Determination of Figure of Merit)

Based on the measured values described above, dimensionless figure of merit ZT of each of the samples of Example 1 and Comparative Example 1 was determined. FIG. 15 shows a result of determination of dimensionless figure of merit ZT of each of the samples of Example 1 and Comparative Example 1 and dimensionless figure of merit ZT of the bulk SiGe shown in JAP352899. As shown in FIG. 15, dimensionless figure of merit ZT of the sample of Example 1 was higher in value than those of the sample of Comparative Example 1 and the bulk SiGe.

[Experiment of Comparing Effects Based on Presence/Absence of Uppermost Layer in Substrate Structure]

(Samples 7 to 9)

Nanoparticles were formed using the production method of the first embodiment or the third embodiment. Specifically, substrate structures were first prepared. The substrate structures thus prepared were: a substrate structure only constituted of a sapphire substrate; and a substrate structure including a sapphire substrate provided with an uppermost layer made of amorphous silicone (a-Si). Then, in the layering step, a first layer constituted of an a-Ge layer, a Au layer, and an a-Ge layer was deposited on each substrate structure such that the a-Ge layer, the Au layer, and the a-Ge layer respectively had thicknesses of 1.3 nm, 0.2 nm, and 1.3 nm, and then Si was deposited thereon to form a second layer constituted of an a-Si layer and having a thickness of 5.2 nm. The concentration of Au in the first layer was set at 3.3 to 4.7 atomic %. Then, the step of layering the first and second layers was repeatedly performed for 40 times. Then, the layered structure was left in an RTA furnace of nitrogen atmosphere under an environment of 500° C. for 15 minutes to perform the annealing step by providing an annealing treatment, thereby forming nanoparticles.

As shown in Table 2 below, a sample 7 employed the substrate structure only constituted of the sapphire substrate, a sample 8 employed the substrate structure including the sapphire substrate provided with the uppermost layer having a thickness of 15 nm, and a sample 9 employed the substrate structure including the sapphire substrate provided with the uppermost layer having a thickness of 30 nm.

TABLE 2

| | Presence or Absence/Thickness of | Concentration of Au |
|---|---|---|
| | Uppermost Layer (a-Si layer) | (Atomic %) |
| Sample 7 | Absent | 4.7 |
| Sample 8 | Present/15 nm | 3.3 |
| Sample 9 | Present/30 nm | 3.5 |

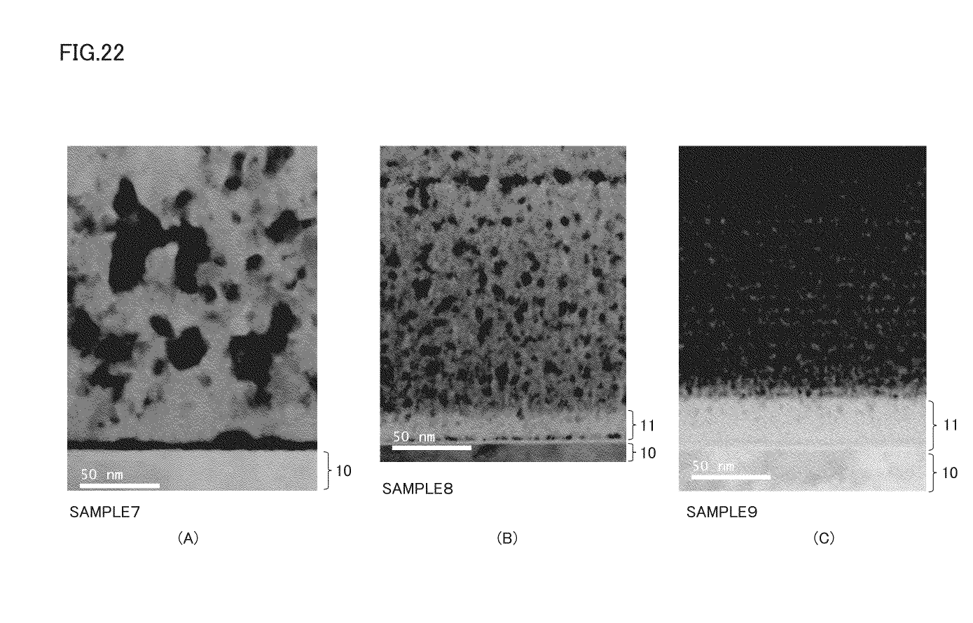

A bright-field STEM (Scanning Transmission Electron Microscopy) image of the layered structure of each of samples 7 to 9 produced as described above was obtained using an electron microscope (device name: JEM-2100F provided by JEOL Co., Ltd.). FIGS. 22(A), (B), and (C) respectively show bright-field STEM images of portions including substrates 10 in samples 7, 8, and 9. In FIG. 22(A), a black portion in the upper layer of sapphire substrate 10 was Au. It should be noted that the fact that the black portion was Au in the STEM image was confirmed by obtaining EDX (energy dispersive X-ray spectroscopy) of the STEM image. As shown in FIG. 22(A), when no uppermost layer was provided on sapphire substrate 10, it was observed that Au is intensively precipitated on a portion of sapphire substrate 10 in contact with the first layer. In FIGS. 22(B) and (C), it was confirmed that Au was diffused in uppermost layer 11 provided on sapphire substrate 10 and there was found no portion on which Au is intensively precipitated in the vicinity of the boundary with uppermost layer 11. It should be noted that also in sample 8 having uppermost layer 11 having a thickness of 15 nm, it was confirmed that Au was diffused in uppermost layer 11 as shown in FIG. 22(B) and could be prevented from being intensively precipitated at a specific portion. Hence, even when the thickness of uppermost layer 11 was 5 nm, which was ⅓ of 15 nm in sample 8, it could be expected that Au was diffused in uppermost layer 11 to prevent Au from being intensively precipitated at a specific portion.

(Measurement of Thermoelectric Voltage)

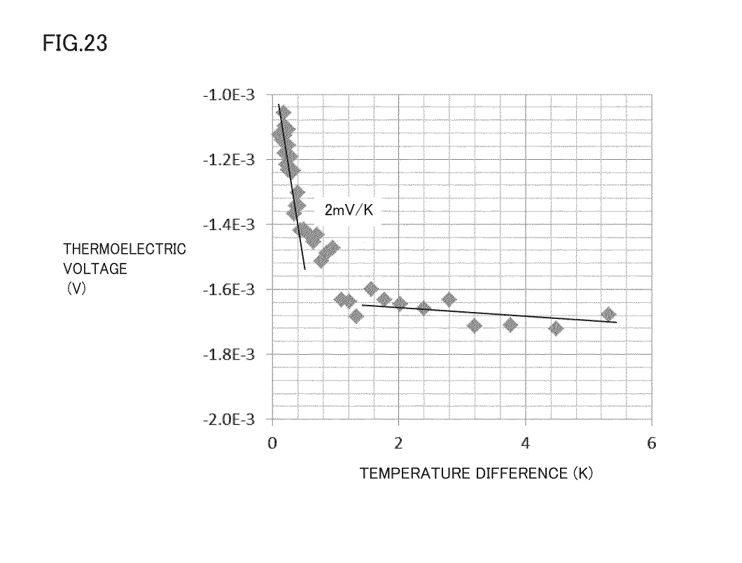

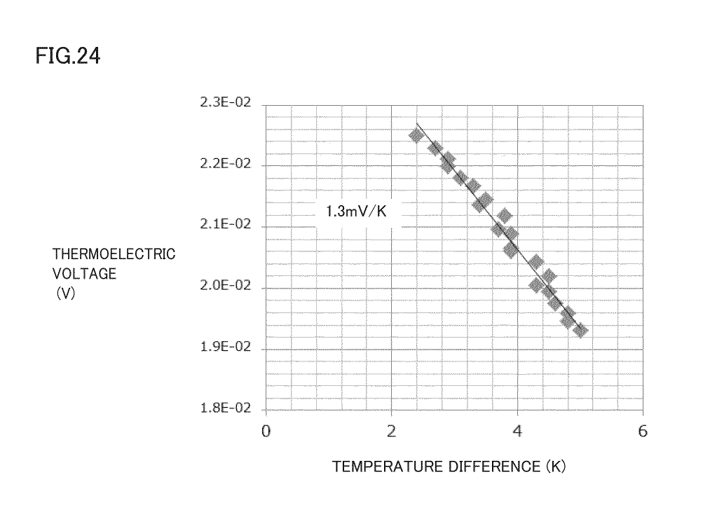

Two electrodes were provided on a surface of each of sample 7 and sample 9, and a temperature difference is provided between the two electrodes to measure thermoelectric voltage using a thermoelectric property measurement device (device name: RZ2001i provided by Ozawa Science Co., Ltd.). FIG. 23 shows a result of measurement of sample 7, and FIG. 24 shows a result of measurement of sample 9. The inclination of a graph for the thermoelectric voltage as shown in each of FIG. 23 and FIG. 24 represents the Seebeck coefficient. When sample 7 was used, it was found that as shown in FIG. 23, a Seebeck coefficient of 2 mV/K is obtained when the temperature difference is not more than 1 K and a high performance thermoelectric material can be provided. When sample 9 was used, it was found that as shown in FIG. 24, a Seebeck coefficient of 1.3 mV/K is obtained when the temperature difference is more than 4 K and a high performance thermoelectric material can be provided.

(Discussion on Thermoelectric Property of Sample 7)

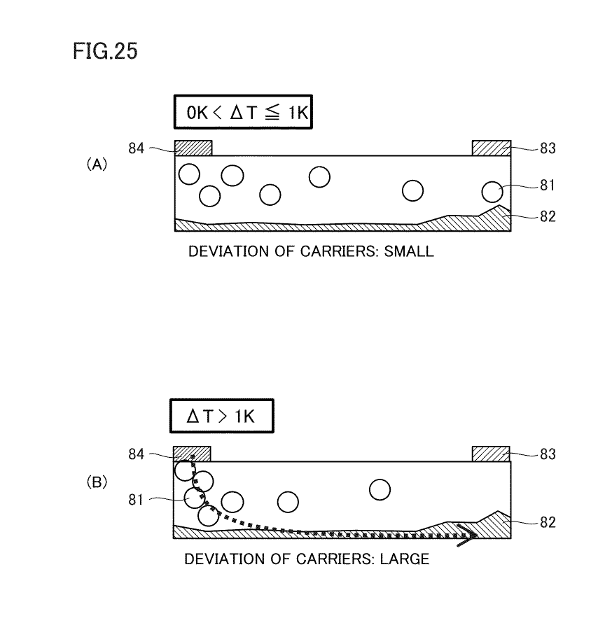

Regarding sample 7, the following discusses a reason why the thermoelectric property differs between a case where the temperature difference was not more than 1 K and a case where the temperature difference was more than 1 K as shown in FIG. 23. In sample 7, as shown in FIG. 22(A), Au is intensively precipitated at a portion of boundary with the sapphire substrate. If the Au precipitated portion is brought into an electrically conductive state through the electrode portions and carriers, a leak path is constructed, thus presumably resulting in decreased thermoelectric property. Specifically, models shown in FIGS. 25(A) and (B) can be considered. FIG. 25(A) shows a model when the temperature difference between electrodes 83, 84 is small, specifically, when the temperature difference is not more than 2 K. In this case, deviation of carriers 81 is small and therefore it is considered that Au precipitated portion 82 does not constitute the leak path. FIG. 25(B) shows a model when the temperature difference between electrodes 83, 84 is large, specifically, when the temperature difference is more than 2K. In this case, deviation of carriers 81 is large and therefore it is considered that Au precipitated portion 82 may constitute the leak path.

### Example 2

Nanoparticles were formed using the production method of the third embodiment. Specifically, an uppermost layer made of amorphous silicone (a-Si) and having a thickness of 30 nm was formed on a sapphire substrate. In the layering step, a first layer constituted of an a-Ge layer, a Au layer and an a-Ge layer was deposited thereon such that the a-Ge layer, the Au layer and the a-Ge layer respectively had thicknesses of 1.3 nm, 0.2 nm, and 1.3 nm and the first layer had a total thickness of 2.8 nm, and then Si was deposited to deposit a second layer constituted of an a-Si layer and having a thickness of 5.2 nm. Then, the step of layering the first and second layers was repeatedly performed for 40 times. It should be noted that the atomic concentration of Au in the first layer was set at 4.7 atomic %. Then, the layered structure was left in an RTA furnace of nitrogen atmosphere under an environment of 500° C. for 15 minutes to perform the annealing step by providing annealing treatment. It should be noted that because a desired particle size X_{d} of the nanoparticles was set at 10 nm and a desired particle distance G_{d} between the nanoparticles was set at 12 nm, thickness T₁ of the first layer in the present example, i.e., 2.8 mm, was determined to satisfy the formula (4) and thickness T₂ of the second layer, i.e., 5.2 nm, was determined to satisfy the formula (2).

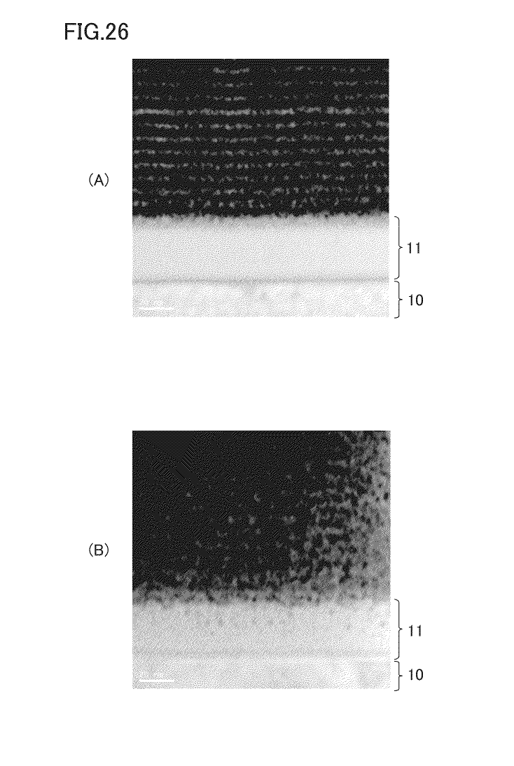

Bright-field STEM images of the layered structure after the layering step and before the annealing step and the layered structure after the annealing step were obtained using an electron microscope (device name: JEM-2100F provided by JEOL Co., Ltd.). FIG. 26(A) shows an enlarged image of the layering portion including sapphire substrate 10 and uppermost layer 11 of the layered structure before the annealing step. FIG. 26(B) shows an enlarged image of the layering portion including sapphire substrate 10 and uppermost layer 11 of the layered structure after the annealing step. As understood from FIGS. 26(A) and (B), it was confirmed that even though the annealing step was performed, Au was not intensively precipitated in the vicinity of the boundary of uppermost layer 11 but was diffused in uppermost layer 11. The layered structure produced in the present example was the same as sample 9 described above, and therefore exhibited the thermoelectric property shown in FIG. 24.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

10: sapphire substrate; 11, 12: uppermost layer; 20, 40: first layer; 21, 23: amorphous Ge layer; 22: Au layer; 30, 50: second layer; 60, 70: substrate structure; 81: carrier; 82: Au precipitated portion; 83, 84: electrode.

1. A method of producing nanoparticles in a base material made of a semiconductor material including a base material element, each nanoparticle including said base material element and a heterogeneous element different from said base material element, the method comprising:
a layering step of alternately layering a first layer and a second layer, said first layer including said heterogeneous element, said second layer not including said heterogeneous element; and
an annealing step of forming said nanoparticles in said base material by performing an annealing treatment onto a layered structure including said first layer and said second layer layered on each other,
in said layering step, said base material element being included in at least one of said first layer and said second layer, said second layer being formed to be thicker than said first layer.

2. The method of producing the nanoparticles according to claim 1, wherein
when a desired particle distance between the nanoparticles to be formed is represented by G_{d}, a thickness T₂ of said second layer is determined in said layering step so as to satisfy the following formula (2), and
an average particle distance Gₘ between the nanoparticles formed in said annealing step satisfies the following formula (3) in relation with the thickness T₂ of said second layer in said layering step:
G_{d}=(2.3±σ₁ )T₂−(1.3±σ₂)(nm) Formula (2), and
Gₘ=(2.3±σ₁ )T₂−(1.3±σ₂)(nm) Formula (3),
where each of σ₁ and σ₂ represents a standard deviation, σ₁ satisfies 0≦σ₁≦0.1, and σ₂ satisfies 0≦σ₂≦1.9.

3. The method of producing the nanoparticles according to claim 1, wherein
when a desired particle size of the nanoparticles to be formed is represented as X_{d}, a thickness T₁ of said first layer is determined in said layering step to satisfy the following formula (4), and
an average particle size Xₘ of the nanoparticles formed in said annealing step satisfies the following formula (5) in relation with the thickness T₁ of said first layer in said layering step:
X_{d}=(32±σ₃)T₁−(81±σ₄)(nm) Formula (4), and
Xₘ=(32±σ₃)T₁−(81±σ₄)(nm) Formula (5),
where each of σ₃ and σ₄ represents a standard deviation, σ₃ satisfies 0≦σ₃≦7, and σ₄ satisfies 0≦σ₄≦20.

4. The method of producing the nanoparticles according to claim 1, wherein
said base material element is Si and Ge,
said heterogeneous element is Au, Cu, B, or Al, and
in said layering step, said first layer includes Ge as said base material element, and said second layer includes Si as said base material element.

5. The method of producing the nanoparticles according to claim 1, wherein
said base material element is N and Ga,
said heterogeneous element is In or Al, and
in said layering step, said first layer and said second layer include N and Ga as said base material element.

6. The method of producing the nanoparticles according to claim 1, wherein
in said layering step, said first layer has a thickness of 2 to 8 nm, and
an average particle size of said nanoparticles formed in said annealing step is 1 to 25 nm, and an average distance between said nanoparticles is 3 to 25 nm.

7. The method of producing the nanoparticles according to claim 1, wherein said annealing step is performed after said layering step.

8. The method of producing the nanoparticles according to claim 1, wherein said annealing step is performed at the same time as said layering step.

9. The method of producing the nanoparticles according to claim 1, wherein said layering step is a step of alternately layering said first layer and said second layer on a substrate structure, and said substrate structure has an uppermost layer that is in contact with at least said first layer and that is formed of a material capable of having solubility of said heterogeneous element.

10. The method of producing the nanoparticles according to claim 9, wherein said uppermost layer of said substrate structure is formed of Si, a semiconductor, glass, ceramics, or an organic substance.

11. The method of producing the nanoparticles according to claim 10, wherein
said base material element is Si and Ge,
said heterogeneous element is Au, Cu, B, or Al, and
said uppermost layer of said substrate structure is formed of Si.

12. The method of producing the nanoparticles according to claim 9, wherein said uppermost layer of said substrate structure has a thickness of not less than 5 nm.

13. A method of producing a thermoelectric material including nanoparticles in a thin film made of a semiconductor material including a base material element, each nanoparticle including said base material element and a heterogeneous element different from said base material element, the method comprising:
a layering step of alternately layering a first layer and a second layer, said first layer including said heterogeneous element, said second layer not including said heterogeneous element; and
an annealing step of forming said nanoparticles in said thin film by performing an annealing treatment onto a layered structure including said first layer and said second layer layered on each other,
in said layering step, said base material element being included in at least one of said first layer and said second layer, said second layer being formed to be thicker than said first layer.

14. The method of producing the thermoelectric material according to claim 13, wherein said layering step is a step of alternately layering said first layer and said second layer on a substrate structure, and said substrate structure has an uppermost layer that is in contact with at least said first layer and that is formed of a material capable of having solubility of said heterogeneous element.

15. A thermoelectric material produced by the method of producing according to claim 13.

16. A thermoelectric material produced by the method of producing according to claim 13, wherein an average particle size of said nanoparticles is 1 to 25 nm, and an average distance between said nanoparticles is 3 to 25 nm.

17. A thermoelectric material produced by the method of producing according to claim 14, wherein said heterogeneous element is diffused in said substrate structure.
